(19) United States
(12) Patent Application Publication
(10) Pub. No.: US 2013/0105212 A1
(43) Pub. Date: May 2, 2013

(54) MULTILAYER INSULATING SUBSTRATE AND METHOD FOR MANUFACTURING THE SAME

(71) Applicant: Japan Electronic Materials Corp., Amagasaki-city (JP)

(72) Inventor: Mitsuaki Tsuboi, Amagasaki-city (JP)

(73) Assignee: Japan Electronic Materials Corp., Amagasaki-city (JP)

(21) Appl. No.: 13/667,080

(22) Filed: Nov. 2, 2012

(30) Foreign Application Priority Data
Nov. 2, 2011 (JP) 2011-241641

(51) Int. Cl. H05K 1/11; H05K 3/40

(52) U.S. Cl. CPC H05K 1/115; H05K 3/4046
USPC 174/264; 29/830

(57) ABSTRACT

A multilayer insulating substrate with excellent electrical characteristics and a method for manufacturing the multilayer insulating substrate. A multilayer insulating substrate is composed of a first insulating layer including first central conductor regions to constitute through electrodes and first outer conductor regions surrounding the first central conductor regions, and a second insulating layer including second central conductor regions to constitute through electrodes and second outer conductor regions surrounding the second central conductor regions, wherein the second insulating layer is laminated on the first insulating layer to allow electrical connection between the first central conductor regions and the second central conductor regions and electrical connection between the first outer conductor regions and the second outer conductor regions so that a coaxial wiring structure is configured by the first outer conductor regions and the second outer conductor regions relative to the first central conductor regions and the second central conductor regions.

### CROSS-REFERENCE TO RELATED APPLICATIONS

This application claims priority of Japanese application number 2011-241641, filed on Nov. 2, 2011, which is incorporated herein by reference in its entirety.

### TECHNICAL FIELD

The present invention relates to a multilayer insulating substrate for use in the probe card or the like and a method for manufacturing the multilayer insulating substrate.

### BACKGROUND ART

Probe card for use in inspection of the semiconductor wafer is provided with a main substrate and a space transformer substrate equipped with a plurality of probe substrates each of which includes arrangement of a probe, wherein a general-purpose ceramic laminated substrate formed with through electrodes is used for the space transformer substrate in order to meet the demand for low thermal expansion and high strength and satisfy particularly required high strength to correspond to multiple pins.

As a method for manufacturing such a general-purpose ceramic laminated substrate, the following method is employed. Through holes for through electrode are formed in predetermined positions of a ceramic green sheet by punching, followed by filling the through holes with a metal paste by using a paste printer. According to such a procedure, a plurality of the green sheets including the through holes filled with a metal paste is laminated, after which the green sheets and the metal paste are sintered by baking to complete a ceramic laminated substrate formed with through electrodes. Such a method for manufacturing a general-purpose ceramic laminated substrate is disclosed in JP 63-136697 as one example.

### SUMMARY OF INVENTION

### Technical Problem

A multilayer insulating substrate such as a ceramic laminated substrate used as a space transformer substrate needs to ensure a sufficient thickness to realize high strength, but a thickness increase of the multilayer insulating substrate is accompanied by a height increase of through electrodes formed in the multilayer insulating substrate and results in extending the length of the electrodes so that a problem arises with deterioration of electric characteristics due to an inductance increase.

Therefore, the present invention aims at, in order to solve such a conventional problem, providing a multilayer insulating substrate including through electrodes of a coaxial wiring structure and a method for manufacturing the multiplayer insulating substrate.

### Solution to Problem

A multilayer insulating substrate according to the present invention is composed of a first insulating layer including first central conductor regions to constitute through electrodes and first outer conductor regions surrounding the first central conductor regions, and a second insulating layer including second central conductor regions to constitute through electrodes and second outer conductor regions surrounding the second central conductor regions, wherein each of the first outer conductor regions and the second outer conductor regions are formed into an annular shape including at least a notched part, the second insulating layer is laminated on the first insulating layer to allow electrical connection between the first central conductor regions and the second central conductor regions and electrical connection between the first outer conductor regions and the second outer conductor regions, and a coaxial wiring structure is configured by the first outer conductor regions and the second outer conductor regions relative to the first central conductor regions and the second central conductor regions, respectively.

Each of the first outer conductor regions and the second outer conductor regions is formed by a plurality of conductors placed by leaving spaces from each other.

In addition, each of the first outer conductor regions and the second outer conductor regions is formed into the same shape and the first outer conductor regions and the second outer conductor regions are turned in the placement to be displaced from each other by using the first central conductor regions and the second central conductor regions as a center, respectively.

Then, each of the conductors is formed into an arc shape so that each of the first outer conductor regions and the second outer conductor regions has a substantially ring shape.

A method for manufacturing a multilayer insulating substrate according to the present invention is characterized in that first central conductor regions penetrating from the front to the back and first outer conductor regions surrounding the first central conductor regions by leaving spaces therebetween and penetrating from the front to the back are formed in a first insulating layer, second central conductor regions penetrating from the front to the back and second outer conductor regions surrounding the second central conductor regions by leaving spaces therebetween and penetrating from the front to the back are formed in a second insulating layer, formation of the first outer conductor regions and the second outer conductor regions includes forming the first outer conductor regions and the second outer conductor regions into an annular shape including at least a notched part and turning the first outer conductor regions and the second outer conductor regions at a predetermined angle by using the first central conductor regions and the second central conductor regions as a center so as to displace the notched part of the annular shape from each other respectively, and the first insulating layer and the second insulating layer are joined to overlap the first central conductor regions and the second central conductor regions for allowing electrical connection between the first central conductor regions and the second central conductor regions and electrical connection between the first outer conductor regions and the second outer conductor regions.

### Advantageous Effects of Invention

A multilayer insulating substrate according to the present invention is composed of a first insulating layer including first central conductor regions to constitute through electrodes and first outer conductor regions surrounding the first central conductor, and a second insulating layer including second central conductor regions to constitute through electrodes and second outer conductor regions surrounding the second central conductor regions, wherein each of the first outer conductor regions and the second outer conductor regions are formed into an annular shape including at least a notched part, the second insulating layer is laminated on the first insulating layer to allow electrical connection between the first central conductor regions and the second central conductor regions and electrical connection between the first outer conductor regions and the second outer conductor regions, and a coaxial wiring structure is configured by the first outer conductor regions and the second outer conductor regions relative to the first central conductor regions and the second central conductor regions, respectively, whereby deterioration of electrical characteristics such as inductance and impedance can be prevented even if the thickness of the substrate is increased.

Each of the first outer conductor regions and the second outer conductor regions is formed by a plurality of conductors placed by leaving spaces from each other, whereby cracks can be prevented from occurring in the outer conductor regions.

In addition, each of the first outer conductor regions and the second outer conductor regions is formed into the same shape and the first outer conductor regions and the second outer conductor regions are turned in the placement to be displaced from each other by using the first central conductor regions and the second central conductor regions as a center respectively, whereby making it possible to match impedance characteristics more accurately.

Then, each of the conductors is formed into an arc shape so that each of the first outer conductor regions and the second outer conductor regions has a substantially ring shape, whereby making it possible to make their shape much closer to a coaxial shape and take a stroke measure while effectively preventing deterioration of electrical characteristics such as impedance characteristics.

A method for manufacturing a multilayer insulating substrate according to the present invention is characterized in that first central conductor regions penetrating from the front to the back and first outer conductor regions surrounding the first central conductor regions by leaving spaces therebetween and penetrating from the front to the back are formed in a first insulating layer, second central conductor regions penetrating from the front to the back and second outer conductor regions surrounding the second central conductor regions by leaving spaces therebetween and penetrating from the front to the back are formed in a second insulating layer, formation of the first outer conductor regions and the second outer conductor regions includes forming the first outer conductor regions and the second outer conductor regions into an annular shape including at least a notched part and turning the first outer conductor regions and the second outer conductor regions at a predetermined angle by using the first central conductor regions and the second central conductor regions as a center so as to displace the notched part of the annular shape from each other respectively, and the first insulating layer and the second insulating layer are joined to overlap the first central conductor regions and the second central conductor regions for allowing electrical connection between the first central conductor regions and the second central conductor regions and electrical connection between the first outer conductor regions and the second outer conductor regions, whereby realizing coaxial wiring in the through electrode and enabling prevention of deterioration of electrical characteristics such as inductance and impedance.

### BRIEF DESCRIPTION OF DRAWINGS

FIG. 1 is a perspective view of multilayer insulating substrate according to the present invention with a partial cutout.

FIG. 2a is a plan view of a first insulating layer and FIG. 2b is a plan view of a second insulating layer.

FIG. 3 is a cross sectional view of the multilayer insulating substrate formed with GND layers on the surface.

FIG. 4a is a plan view of a green sheet serving as the first insulating layer and formed with through holes and FIG. 4b is a plan view of a green sheet serving as the second insulating layer and formed with through holes.

FIG. 5 includes plan views of the first insulating layer and the second insulating layer in which each of outer conductor regions is formed by eight of arc-shaped conductors.

FIG. 6 includes plan views of the first insulating layer and the second insulating layer in which each of outer conductor regions is formed by four of linear conductors.

FIG. 7 includes plan views of the first insulating layer and the second insulating layer in which each of outer conductor regions is formed by eight of linear conductors.

FIG. 8 is a schematic three-dimensional drawing of an outer conductor region formed by eight of linear conductors.

### DESCRIPTION OF EMBODIMENTS

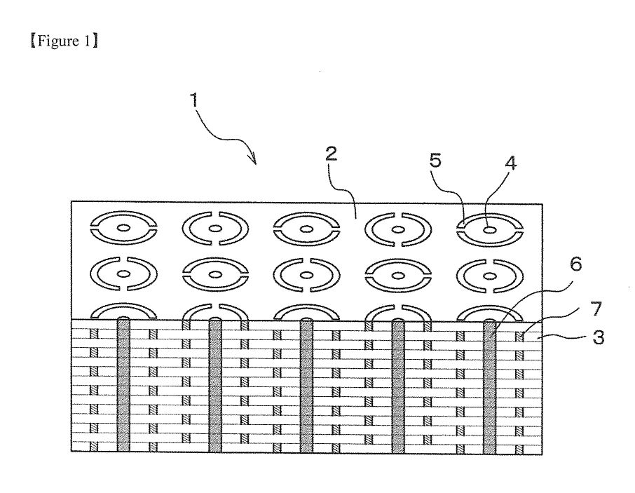

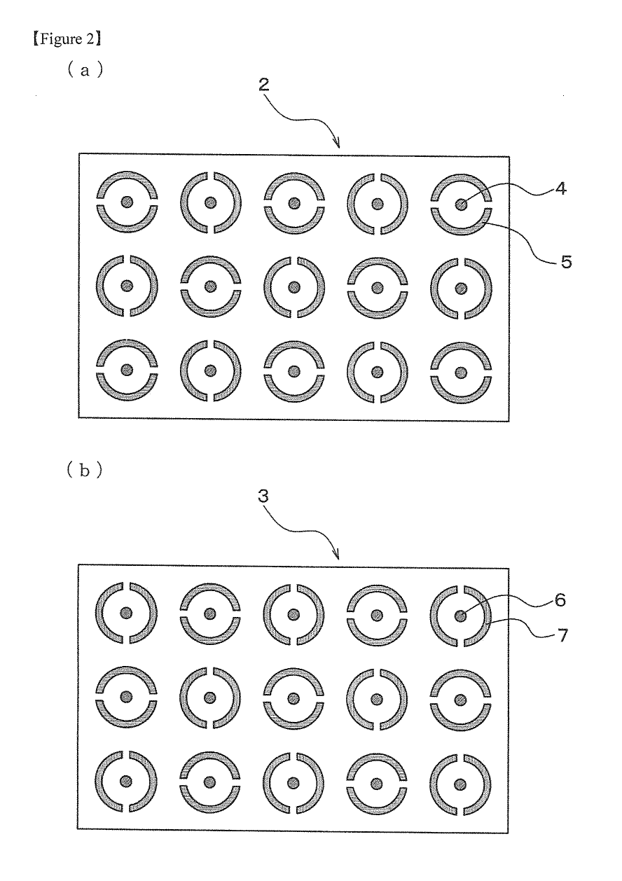

A multilayer insulation substrate 1 and a method for manufacturing the same according to the present invention will be explained below by using drawings. FIG. 1 is a perspective view of the multilayer insulating substrate 1 according to the present invention and FIG. 2 includes plan views of a first insulating layer 2 and a second insulating layer 3 to constitute the multilayer insulating substrate 1.

The multilayer insulating substrate 1 is an laminated substrate formed by laminating the first insulating layers 2 and the second insulating layers 3 alternately, wherein the first insulating layer 2 is provided with first central conductor regions 4 each of which has a circular shape and first outer conductor regions 5 surrounding the first central conductor regions 4 and the second insulating layer 3 is provided with second central conductor regions 6, each of which has a circular shape and constitutes a through electrode, and second outer conductor regions 7 surrounding the second central conductor regions 6.

Each of the first outer conductor regions 5 and the second outer conductor regions 7 is formed by a plurality of conductors placed by leaving spaces from each other. In the embodiment shown in FIGS. 1 and 2, two of arc-shaped conductors are placed to surround each of the first central conductor regions 4 and the second central conductor regions 6 so that each of the first outer conductor regions 5 and the second outer conductor regions 7 is formed into a substantially ring shape.

When the first insulating layers 2 and the second insulating layers 3 are laminated alternately, the first central conductor regions 4 and the second central conductor regions 6 are arranged to overlap one above the other and electrically connected to form columnar through electrodes. Then, the first outer conductor regions 5 are placed on the upper side and the second outer columnar regions 7 are placed on the lower side to form a substantially cylindrical shape and electrically connected, whereby a coaxial wiring structure is configured by the first outer conductor regions 5 and the second outer conductor regions 7 relative to the first central conductor regions 4 and the second central conductor regions 6.

Although the first outer conductor regions 5 and the second outer conductor regions 7 are placed to overlap one above the other, instead of being placed to overlap in the same direction, they are turned in the placement to be displaced from each other by using the first central conductor regions 4 and the second central conductor regions 5 as a center, respectively. Here, the second outer conductor regions 7 are turned at 90 degrees and displaced in the placement relative to the first outer conductor regions 5. Owing to this placement, notches of the annular first outer conductor regions 5 and notches of the annular second outer conductor regions 7 do not overlap each other vertically as shown in the cross section of FIG. 1, whereby electric connection is ensured to each other and a coaxial wiring structure of a substantially cylindrical shape is constructed.

The first insulating layer 2 is formed with a plurality of the first central conductor regions 4 and the first outer conductor regions 5 as shown in FIG. 2a and according to the number and placement of the first central conductor regions 4 and the first outer conductor regions 5 formed in the first insulating layer 2, a plurality of the second central conductor regions 6 and the second outer conductor regions 7 is also formed in the insulating layer 3 as shown in FIG. 2b.

For example, in the first insulating layer 2, a plurality of the first central conductor regions 4 is placed at equal intervals from front to back and from left to right and the first outer conductor regions 5 are placed to surround the first central conductor regions 4. At this time, as shown in FIG. 2a, to the first outer conductor regions 5 adjacent in the front, back, left and right are turned in the placement to be displaced from each other by using the first central conductor regions 4 as a center so that notches thereof are positioned differently from each other. Here, they are turned in the placement so as to displace the position of the notches at 90 degrees from each other.

In accordance with such a placement of the first outer conductor regions 5 in the first insulating layer 2, the second central conductor regions 6 and the second outer conductor regions 7 are placed in the second insulating layer 3. The second central conductor regions 6 are placed according to the same number and the same positions as the first central conductor regions 4, while the second outer conductor regions 7 are, as stated above, turned in the placement at 90 degrees to the first outer conductor regions 5 positioned above and below as shown in FIG. 2b. Owing to this placement, the second outer conductor regions 7 are turned in the placement to displace the position of the notches at 90 degrees from that of the adjacent second outer conductor regions 7 in the front, back, left and right in the second insulating layer 3.

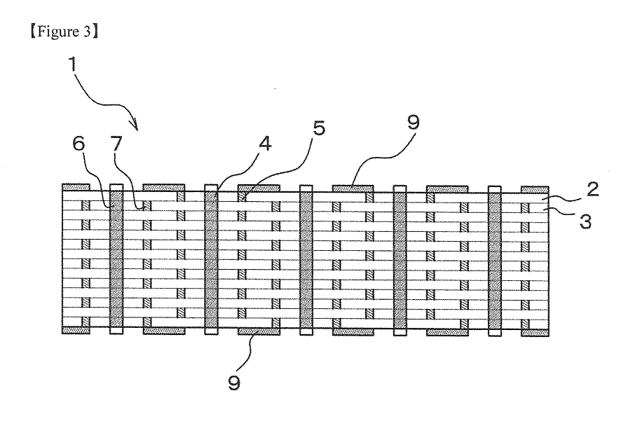

Then, as shown in FIG. 3, a GND pattern 9 is formed into a thin film on the front surface and the undersurface of the multilayer insulating substrate 1 and when it is connected to the laminated outer conductor regions 5 and 7, coaxial wiring is completed in the multilayer insulating substrate 1 and the substrate with excellent electrical characteristics is realized. In the multilayer insulating substrate 1 according to the present invention, pseudo-coaxial electrodes are formed by the central conductor regions 4 and 6 and the outer conductor regions 5 and 7, whereby making it possible to suppress the rise of inductance and/or impedance in response to an increased thickness of the substrate.

Next, a method for manufacturing the multilayer insulating substrate 1 according to the present invention will be explained. First of all, a ceramic green sheet 12 being an unsintered ceramic molding is prepared. The ceramic green sheet 12 is obtained by mixing alumina powder serving as a ceramic powder body, organic binder, solvent and plasticizer or other materials to produce slurry and forming a ceramic into a sheet by using the doctor blade method or the calender roll method or other methods.

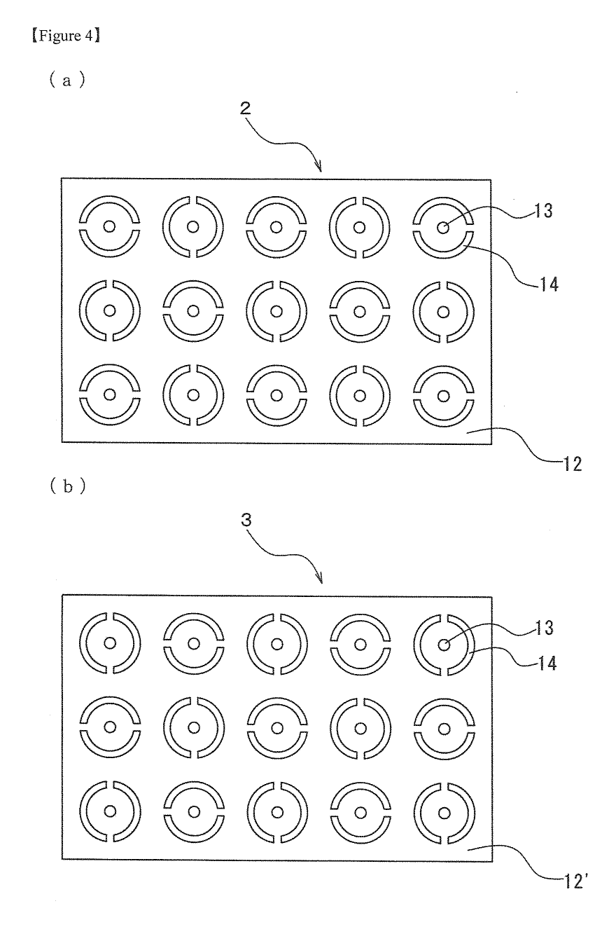

Next, two kinds of through holes are formed by punching in the ceramic green sheet 12 as shown in FIG. 4a. One is a circular through hole 13 for formation of the first central conductor regions 4. A plurality of the circular through holes 13, each of which is set to, for example, a size of 00.1 mm, is formed at equal intervals vertically and horizontally with a pitch of 1.0 mm.

The other is an arc-shaped through hole 14. Two of the arc-shaped through holes 14 are formed by leaving predetermined spaces therebetween so as to surround the circular through hole 13 as shown in FIG. 4a. If the paired arc-shaped through holes 14 are connected to form a ring which is subjected to punching, a sheet held between the through hole 13 and the through holes 14 will come off, which explains why the paired arc-shaped through holes 14 are formed by leaving predetermined spaces that are used as parts to connect a space between the through hole 13 and the through holes 14 to the outside of the through holes 14. If a method is used to prevent a sheet between the through hole 13 and the through holes 14 from coming off without arranging such connection parts, the through holes 14 can be formed into a ring shape.

The paired arc-shaped through holes 14 are set to have an outer diameter of Ø0.8 mm and an inner diameter of 0.64 mm. Further, the connection parts positioned between the paired arc-shaped through holes 14 are set to have a width of 0.08 mm and placed so that the connection parts of the paired arc-shaped through holes 14 of the through holes 13 adjacent in the front, back, left and right are positioned differently from each other. In FIG. 4a, there are two kinds of placements for the paired arc-shaped through holes 14, including one for disposing the connection parts vertically and the other for disposing the connection parts horizontally, wherein they are displaced from each other at 90 degrees in the circumferential direction.

After thus forming the circular through holes 13 and the arc-shaped through holes 14, the circular through holes 13 and the arc-shaped through holes 14 are filled with a conductive paste which is a metal paste here by pattern printing. As a result, the ceramic green sheet 12 in which the circular through holes 13 and the arc-shaped through holes 14 are filled with a metal paste is completed. Such a ceramic green sheet 12 serves as the first insulating layer 2 shown in FIG. 2a.

Next, a ceramic green sheet 12′ to be laminated alternately with the ceramic green sheet 12 will be explained. Firstly, the ceramic green sheet 12′ being an unsintered ceramic molding is prepared. The circular through holes 13 are formed in the green sheet 12′ in the same positions and the same size as those of the circular through holes 13 formed in the green sheet 12. Then, two of the arc-shaped through holes 14 are formed by leaving spaces therebetween so as to surround the circular through holes 13, wherein connection parts being the spaces interposed between the paired arc-shaped through holes 14 are placed differently from the connection parts being the spaces interposed between the paired arc-shaped through holes 14 formed in the green sheet 12 or disposed horizontally corresponding to the vertically disposed connection parts and disposed vertically corresponding to the horizontally disposed connection parts.

After thus forming the circular through holes 13 and the arc-shaped through holes 14, the circular through holes 13 and the arc-shaped through holes 14 are filled with a metal paste. As a result, the ceramic green sheet 12′ in which the circular through holes 13 and the arc-shaped through holes 14 are filled with a metal paste is completed. Such a ceramic green sheet 12′ serves as the second insulating layer 3 shown in FIG. 2b.

The green sheets 12 and the green sheets 12′ formed as stated above are laminated alternately by positioning the circular through holes 13 filled with a metal paste to overlap one above the other. Pressure is applied to the green sheets 12 and the green sheets 12′ in a state of being laminated alternately in order to form a ceramic laminated body.

Thereafter, by heating the ceramic laminated body at 1500 to 1800° C. to sinter the ceramic green sheets 12 and 12′ and the metal paste, the metal paste is formed into conductors to complete formation of the first central conductor regions 4 and the first outer conductor regions 5 by which the green sheet 12 is turned into the first insulating layer 2, and complete formation of the second central conductor regions 6 and the second outer conductor regions 7 by which the green sheet 12′ is turned into the second insulating layer 3, so that the multilayer insulating substrate 1 according to the present embodiment is completed as shown in FIG. 1.

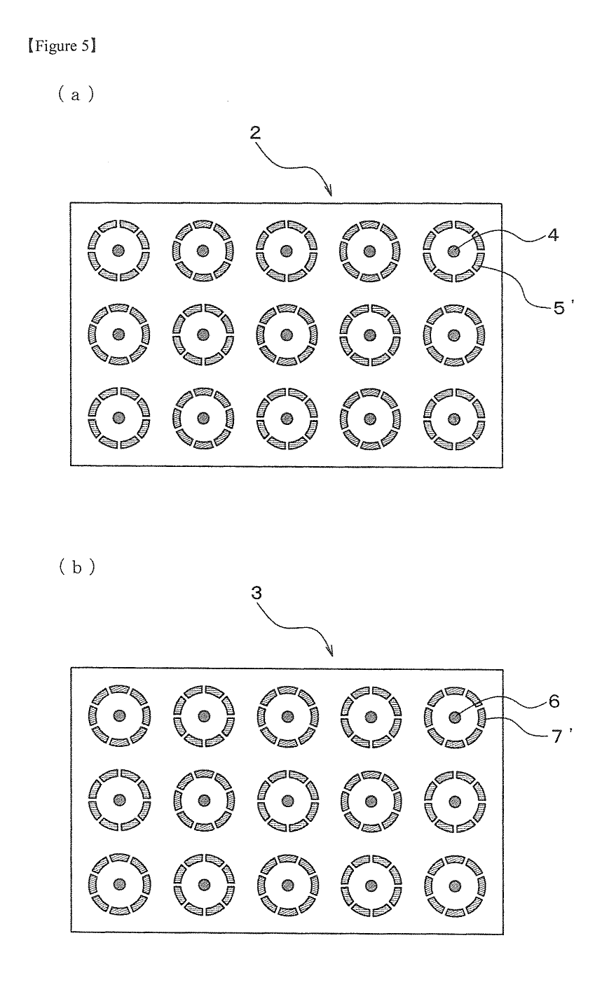

Although each of the first outer conductor regions 5 and the second outer conductor regions 7 is structured by the paired arc-shaped conductors in the above explanation of the multilayer insulating substrate 1, the shape and number of the conductors can be modified. FIG. 5 illustrates the first insulating layer 2 and the second insulating layer 3 in which each one of the first outer conductor regions 5′ and the second outer conductor regions 7′ is formed by eight of arch-shaped conductors. At this time, the position of notches of the first outer conductor regions 5′ disposed on the upper side and the position of notches of the second outer conductor regions 7′ disposed on the lower side are displaced from each other at 22.5 degrees in the circumferential direction in the placement. Owing to such a placement, a coaxial shape is formed by the first outer conductor regions 5′ and the second outer conductor regions 7′.

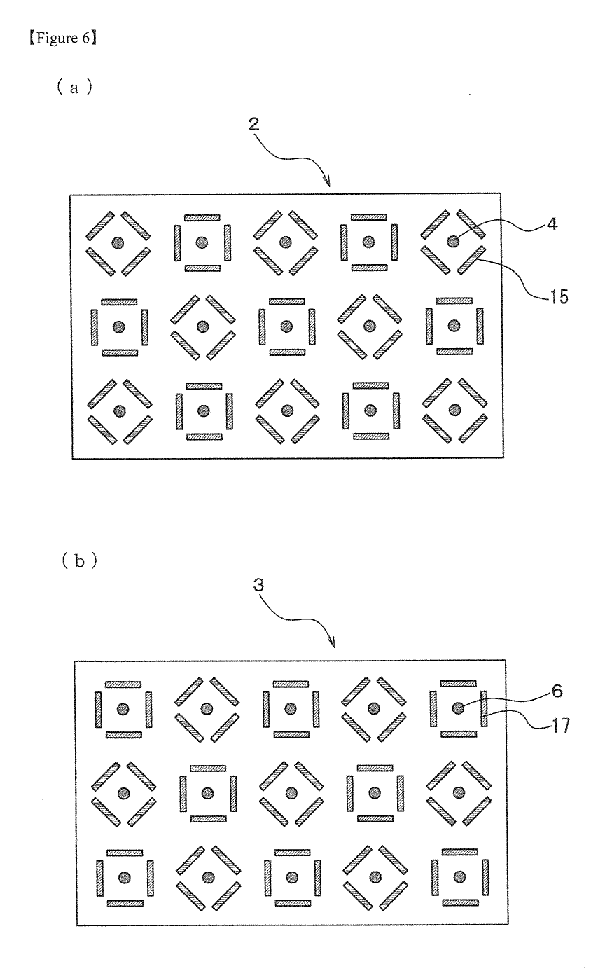

When the first outer conductor regions 5 and 5′ and the second outer conductor regions 7 and 7′ are formed by arc-shaped conductors, cracks may possibly occur in a curved part of each conductor. Such cracks can be prevented by using linear conductors by which the first outer conductor regions 5 and 5′ and the second outer conductor regions 7 and 7′ are formed. FIG. 6 illustrates the first insulating layer 2 and the second insulating layer 3 in which such linear conductors are used to form the first outer conductor regions 15 and the second outer conductor regions 17.

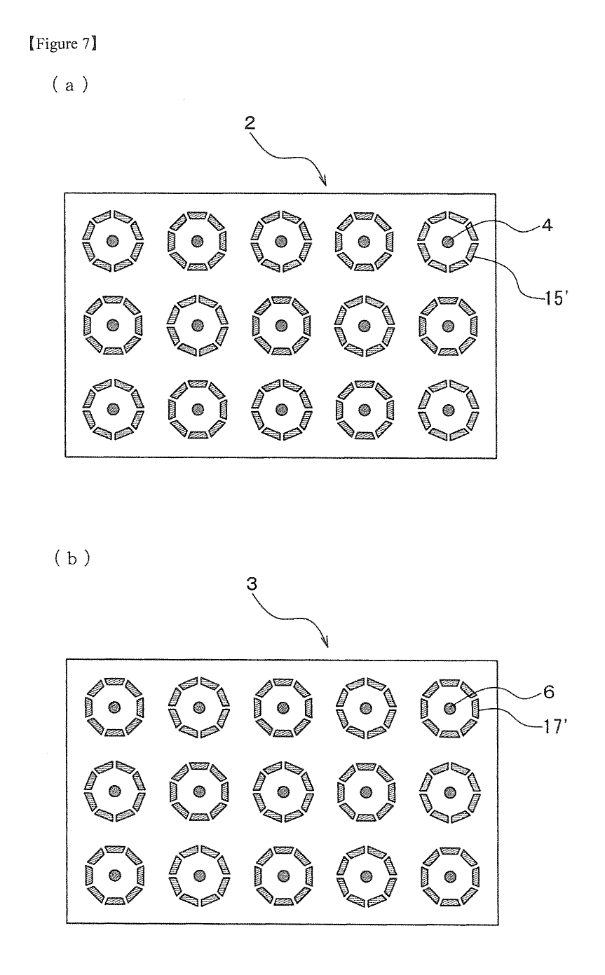

FIG. 6 shows a rectangular ring shape into which each of the first outer conductor regions 5 and the second outer conductor regions 7 was formed by using four linear conductors. When each of the two conductor thus has a long shape, there are areas that are significantly different in the distance from the central conductor regions 4 and 6 and as a method to solve this issue, eight of linear conductors are preferably used to form each of the first outer conductor regions 15′ and the second outer conductor regions 17′ as shown in FIG. 7.

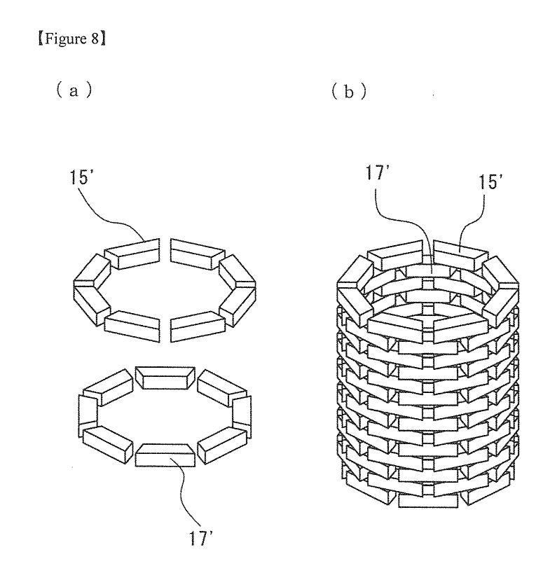

When eight of linear conductors are thus used to form each of the first outer conductor regions 15′ and the second outer conductor regions 17′ as shown in FIG. 8a, as shown in a schematic three-dimensional drawing of FIG. 8b including only the outer conductor regions 15′ and 17′, a conductor of a substantially cylindrical shape is formed by the first outer conductor regions 15′ and the second outer conductor regions 17′, whereby making it possible for both crack prevention and a more preferable coaxial shape to coexist.

When such a multilayer insulating substrate 1 according to the present invention is used as a space transformer substrate for probe card, excellent performance can be provided in an impedance matching design, while making it possible to correspond to multiple pins and help to improve probe card performance. It is also possible to exhibit excellent electrical characteristics for other purposes without being limited to the probe card.

What has been described above are preferred aspects of the present invention. It is of course not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, combinations, modifications, and variations that fall within the spirit and scope of the appended claims.

What is claimed is:

1. A multilayer insulating substrate comprising:
a first insulating layer including first central conductor regions to constitute through electrodes and first outer conductor regions surrounding the first central conductor regions; and
a second insulating layer including second central conductor regions to constitute through electrodes and second outer conductor regions surrounding the second central conductor regions; wherein
the first outer conductor regions and the second outer conductor regions are formed into an annular shape including at least a notched part; and
the second insulating layer is laminated on the first insulating layer to allow electrical connection between the first central conductor regions and the second central conductor regions and electrical connection between the first outer conductor regions and the second outer conductor regions, and a coaxial wiring structure is configured by the first outer conductor regions and the second outer conductor regions relative to the first central conductor regions and the second central conductor regions.

2. The multilayer insulating substrate according to claim 1, wherein each of the first outer conductor regions and the second outer conductor regions is formed by a plurality of conductors placed by leaving spaces from each other.

3. The multilayer insulating substrate according to claim 2, wherein each of the first outer conductor regions and the second outer conductor regions is formed into the same shape, and the first outer conductor regions and the second outer conductor regions are turned in the placement to be displaced from each other by using the first central conductor regions and the second central conductor regions as a center, respectively.

4. The multilayer insulating substrate according to claim 2, wherein each of the conductors is formed into an arc shape to form each of the first outer conductor regions and the second outer conductor regions into a substantially ring shape.

5. A method for manufacturing a multilayer insulating substrate comprising the steps of:
forming in a first insulating layer first central conductor regions penetrating from the front to the back and first outer conductor regions surrounding the first central conductor regions by leaving spaces therebetween and penetrating from the front to the back;
forming in a second insulating layer second central conductor regions penetrating from the front to the back and second outer conductor regions surrounding the second central conductor regions by leaving spaces therebetween and penetrating from the front to the back;
formation of the first outer conductor regions and the second outer conductor regions includes forming each of the first outer conductor regions and the second outer conductor regions into an annular shape including at least a notched part and turning the first outer conductor regions and the second outer conductor regions at a predetermined angle to displace the notched parts of the annular shape from each other by using the first central conductor regions and the second central conductor regions as a central axis, respectively; and
joining the first insulating layer and the second insulating layer to overlap the first central conductor regions and the second central conductor regions, allowing electrical connection between the first central conductor regions and the second central conductor regions and electrical connection between the first outer conductor regions and the second outer conductor regions.
